(19) United States
(12) Patent Application Publication
(10) Pub. No.: US 2026/0247947 A1
(43) Pub. Date: Aug. 20, 2026

(54) SEMICONDUCTOR DEVICE

(71) Applicant: Socionext Inc., Kanagawa (JP)

(72) Inventors: Atsushi OKAMOTO, Yokohama (JP); Hirotaka TAKENO, Yokohama (JP); Wenzhen WANG, Yokohama (JP)

(21) Appl. No.: 19/643,055

(22) Filed: Apr. 9, 2026

Related U.S. Application Data
(63) Continuation of application No. PCT/JP2023/037171, filed on Oct. 13, 2023.

(51) Int. Cl. H10W 20/41; H10D 30/00; H10D 30/43; H10D 84/85; H10W 20/20; H10W 20/42; H10W 20/43

(52) U.S. Cl. CPC H10W 20/427; H10D 30/43; H10D 30/502; H10D 84/851; H10W 20/2134; H10W 20/422; H10W 20/43; H10W 20/435

(57) ABSTRACT

A semiconductor device includes: a substrate; first, second, and third power supply lines formed over a first surface of the substrate; a first semiconductor layer formed above a second surface of the substrate opposite the first surface and electrically connected to the first power supply line; a second semiconductor layer formed above the second surface of the substrate and electrically connected to the second power supply line; a third semiconductor layer formed at a position overlapping with the first semiconductor layer in a plan view; a fourth semiconductor layer formed at a position overlapping with the second semiconductor layer in a plan view; a first gate formed on the substrate between the first semiconductor layer and the second semiconductor layer and between the third semiconductor layer and the fourth semiconductor layer; and a first transistor including the first semiconductor layer, the second semiconductor layer, and the first gate.

### CROSS-REFERENCE TO RELATED APPLICATIONS

This application is a continuation application of International Application No. PCT/JP2023/037171 filed on Oct. 13, 2023, and designated the U.S., the entire contents of which are incorporated herein by reference.

### TECHNICAL FIELD

The present invention relates to a semiconductor device.

### BACKGROUND ART

A complementary field effect transistor (CFET) technique, in which the CFET is formed by stacking transistors, is known. In a backside power delivery network (BS-PDN) which supplies a power supply potential from the back surface of a semiconductor substrate, a technique is known in which vias such as through silicon vias (TSV) are directly connected to the source and drain of a transistor. A technique is known in which a power switch circuit for controlling on/off of supply of a power supply potential is provided in a standard cell or the like.

### RELATED ART DOCUMENTS

### Patent Documents

Patent Document 1: U.S. Patent Application Publication No. 2023/0178435

Patent Document 2: U.S. Patent Application Publication No. 2023/0067311

Patent Document 3: U.S. Patent Application Publication No. 2022/0123023

Patent Document 4: U.S. Patent Application Publication No. 2022/0181258

Patent Document 5: International Publication No. 2020/065916

Patent Document 6: International Publication No. 2020/066797

Patent Document 7: International Publication No. 2020/217396

Patent Document 8: International Publication No. 2020/217400

Patent Document 9: U.S. Patent Application Publication No. 2021/0366902

Patent Document 10: U.S. Patent Application Publication No. 2022/0102479

Patent Document 11: U.S. Patent Application Publication No. 2021/0210600

### SUMMARY OF THE INVENTION

In one aspect of the present disclosure, a semiconductor device includes: a substrate; a first power supply line, a second power supply line, and a third power supply line formed over a first surface of the substrate; a first semiconductor layer formed above a second surface of the substrate opposite the first surface and electrically connected to the first power supply line; a second semiconductor layer formed above the second surface of the substrate and electrically connected to the second power supply line; a third semiconductor layer formed at a position overlapping with the first semiconductor layer in a plan view; a fourth semiconductor layer formed at a position overlapping with the second semiconductor layer in a plan view; a first gate formed on the substrate between the first semiconductor layer and the second semiconductor layer and between the third semiconductor layer and the fourth semiconductor layer; a first transistor including the first semiconductor layer, the second semiconductor layer, and the first gate; a first via formed in the substrate and positioned overlapping with the first semiconductor layer in a plan view and connected to the first semiconductor layer and the first power supply line; a fifth semiconductor layer and a sixth semiconductor layer formed above the second surface of the substrate; a seventh semiconductor layer formed on the fifth semiconductor layer; an eighth semiconductor layer formed on the sixth semiconductor layer; a second gate formed on the substrate between the fifth semiconductor layer and the sixth semiconductor layer and between the seventh semiconductor layer and the eighth semiconductor layer; a second transistor including the fifth semiconductor layer, the sixth semiconductor layer, and the second gate; a third transistor including the seventh semiconductor layer, the eighth semiconductor layer, and the second gate; and a control circuit including the second transistor and the third transistor, wherein one of the fifth semiconductor layer or the sixth semiconductor layer is electrically connected to the first power supply line, one of the seventh semiconductor layer or the eighth semiconductor layer is electrically connected to the third power supply line, and the other of the fifth semiconductor layer or the sixth semiconductor layer and the other of the seventh semiconductor layer or the eighth semiconductor layer are electrically connected to the first gate.

### BRIEF DESCRIPTION OF THE DRAWINGS

FIG. 1 is a plan view showing an example of a layout of a semiconductor device according to a first embodiment;

FIG. 2 is a cross-sectional view showing an example of a cross-sectional structure of the semiconductor device of FIG. 1;

FIG. 3 is a circuit diagram showing an example of a circuit arranged in a block with respect to a standard cell of FIG. 1;

FIG. 4 is a circuit diagram showing an example of a power switch circuit of FIG. 3;

FIG. 5 is a perspective view showing an example of a part of a layout of the power switch circuit and the standard cell of FIG. 3;

FIG. 6 illustrates perspective views showing examples of a method of connecting a top wiring and a wiring of a BSM1 layer formed on the back surface of a substrate;

FIG. 7 is a plan view showing an example of a plan view of the power switch circuit and the standard cell of FIG. 5 as viewed from a top-wiring side toward a substrate SUB;

FIG. 8 is a plan view showing an example of a plan view of the power switch circuit and the standard cell of FIG. 5 as viewed from a bottom wiring side toward a substrate side;

FIG. 9 is a plan view showing an example of a plan view of the BSM1 layer and BSM2 layer in a region where the power switch circuit and the standard cell of FIG. 5 are formed;

FIG. 10 is a cross-sectional view showing an example of a cross section taken along a line X1-X1′ of FIGS. 7 to 9;

FIG. 11 is a cross-sectional view showing an example of a cross section taken along a line X2-X2′ of FIGS. 7 to 9;

FIG. 12 is a cross-sectional view showing an example of a cross section taken along a line Y1-Y1′ of FIGS. 7 to 9;

FIG. 13 is a perspective view showing an example of a layout of the power switch circuit and the standard cell in a second embodiment;

FIG. 14 is a plan view showing an example of a plan view of the power switch circuit and the standard cell of FIG. 13 when viewed from the top-wiring side toward the substrate SUB; and

FIG. 15 is a plan view showing an example of the plan view of the power switch circuit and the standard cell of FIG. 13 when viewed from the bottom wiring side toward the substrate side.

### DETAILED DESCRIPTION OF THE INVENTION

When a power switch circuit is formed by directly connecting a source or a drain of a CFET to a TSV, how the power switch circuit should be laid out has not been studied in detail.

It is an object of the present disclosure to appropriately lay out a power switch circuit formed by using a CFET whose source and drain are directly connected to a TSV.

Embodiments will now be described with reference to the drawings. Hereinafter, a sign indicating a signal is also used as a sign indicating a signal line or a signal terminal. A sign indicating a power supply potential is also used as a sign indicating a power supply line or a power supply terminal to which the power supply potential is supplied.

### First Embodiment

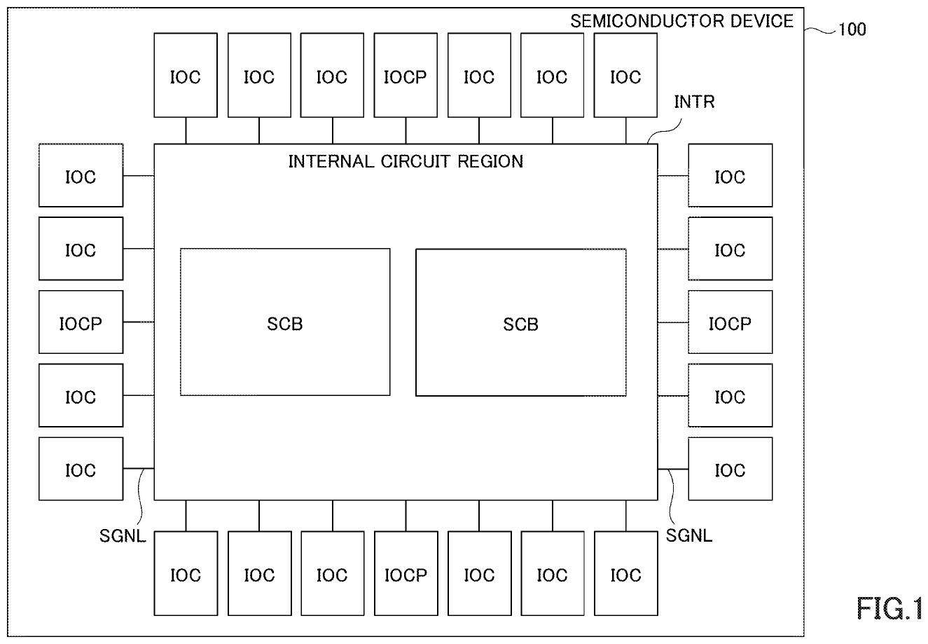

FIG. 1 shows an example of a layout of a semiconductor device according to a first embodiment. For example, a semiconductor device 100 shown in FIG. 1 may be a system on chip (SoC) or a single field-programmable gate array (FPGA).

The semiconductor device 100 includes a plurality of input/output (I/O) cells IOC and IOCP, and an internal circuit region INTR. The I/O cell IOC is an interface circuit for a signal SGNL such as an input signal, an output signal, or an input/output signal. The I/O cell IOCP is an interface circuit for a power supply potential or a ground potential.

Each of the I/O cells IOC and IOCP is connected to the internal circuit region INTR. For example, the internal circuit region INTR includes one or more standard cell blocks SCB in which standard cells are provided. In the internal circuit region INTR, logic circuits other than standard cells may be mounted, and a memory may be mounted. The memory may be mounted in the standard cell block SCB.

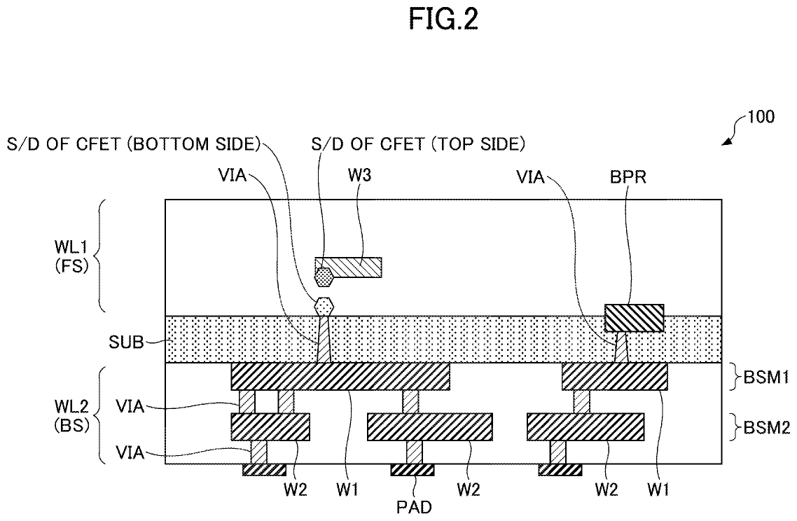

FIG. 2 shows an example of a cross-sectional structure of the semiconductor device 100 of FIG. 1. The semiconductor device 100 includes a substrate SUB, a wiring layer WL1 formed on a front surface FS side of the substrate SUB, and a wiring layer WL2 formed on a back surface BS side of the substrate SUB. The front surface FS of the substrate SUB is an example of a second surface, and the back surface BS of the substrate SUB is an example of a first surface. On the front surface FS of the substrate SUB, a source S and a drain D (hereinafter, may be inclusively indicated as “S/D”), which are parts of a CFET, are formed on a bottom side, which is a side close to the substrate SUB, and on a top side, which is a side far from the substrate SUB.

The wiring layer WL2 includes a plurality of interconnect layers BSM1 and BSM2 (“BSM” stands for backside metal, and two wiring layers are shown in FIG. 2). A pad PAD serving as an external connection terminal is formed on a surface (back surface) of the wiring layer WL2 opposite to the substrate SUB. For example, interconnects W1 and W2 for supplying a power supply potential, a ground potential, and the like are formed on the interconnect layers BSM1 and BSM2, respectively. The interconnects W1 and W2 are mutually connected via a via VIA, and the interconnects W2 and the pad PAD are mutually connected via a via VIA. Hereinafter, the interconnect layers BSM1 and BSM2 are also referred to as a BSM1 layer or a BSM2 layer.

The interconnects W1 of the wiring layer WL2 are connected to the bottom-side source S/drain D (S/D) of the CFET via a via VIA such as a TSV formed in the substrate SUB. The interconnects W1 may be connected to an embedded BPR (Buried Power Rail) interconnect, embedded in the front surface of the substrate SUB, via a via VIA such as a TSV. Note that the wiring layer WL2 may be a wiring layer formed on the back surface of the substrate SUB or a wiring layer formed on another chip bonded to the back surface of the substrate SUB. The source S/drain D (S/D) of the CFET may be connected to an interconnect W3 formed in the wiring layer WL1.

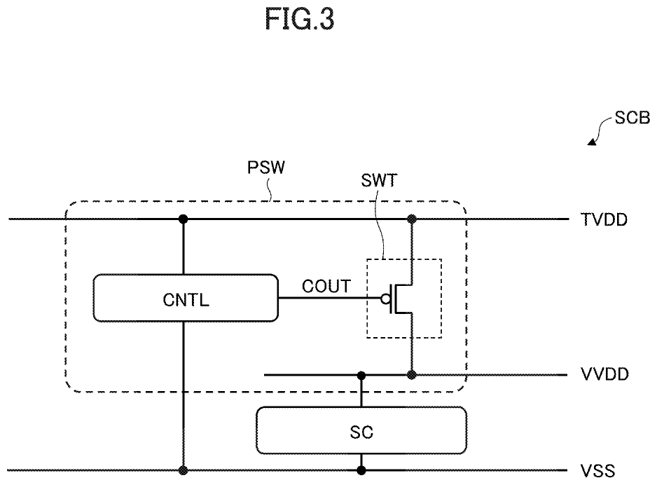

FIG. 3 shows an example of a circuit arranged in the standard cell block SCB of FIG. 1. The standard cell block SCB includes a power switch circuit PSW and a standard cell SC. The standard cell SC is connected to a virtual power supply line VVDD and a ground line VSS, and is operated by receiving a virtual power supply potential VVDD from the virtual power supply line VVDD. The standard cell SC includes various logic circuits.

The power switch circuit PSW operates by being connected to a power supply line TVDD and the ground line VSS. The power switch circuit PSW includes a control circuit CNTL and a switch transistor SWT. The switch transistor SWT is an example of a first transistor. For example, the control circuit CNTL generates a control signal COUT for controlling the switch transistor SWT in accordance with an input signal (not illustrated). The power supply line TVDD is an example of a first power supply line, the virtual power supply line VVDD is an example of a second power supply line, and the ground line VSS is an example of the third power supply line.

The switch transistor SWT includes a PMOS transistor whose source is connected to the power supply line TVDD and whose drain is connected to the virtual power supply line VVDD, and is operated by receiving the voltage of the control signal COUT from the control circuit CNTL as a gate potential. While the switch transistor SWT is on, the power supply line TVDD and the virtual power supply line VVDD are electrically connected, and a power supply potential TVDD is supplied to the standard cell SC via the virtual power supply line VVDD. While the switch transistor SWT is off, the electrical connection between the power supply line TVDD and the virtual power supply line VVDD is interrupted, and the virtual power supply line VVDD is set to a floating state.

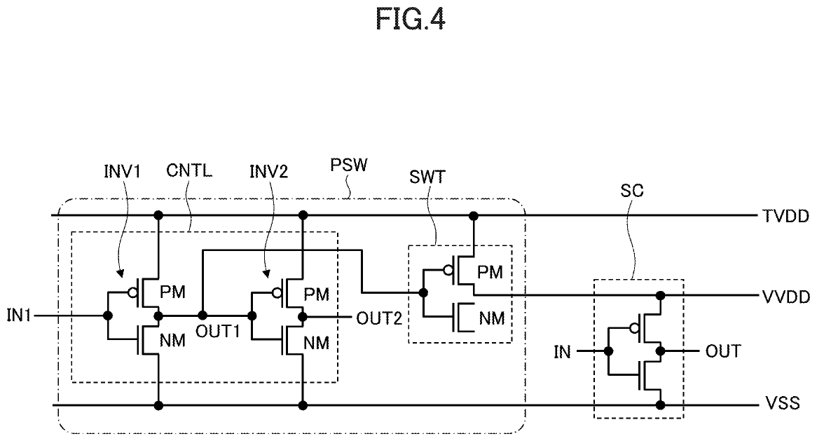

FIG. 4 shows an example of the circuit of the power switch circuit PSW of FIG. 3. The power switch circuit PSW includes a control circuit CNTL and a switch transistor SWT controlled by the control circuit CNTL.

For example, the control circuit CNTL is a buffer circuit including inverters INV1 and INV2 connected in series between an input signal line IN1 and an output signal line OUT2. The inverters INV1 and INV2 operate by being connected to the power supply line TVDD and the ground line VSS. The inverter INV1 inverts the logic value of the input signal IN1 and outputs the inverted input signal IN1 as an output signal OUT1. The inverter INV2 inverts the logic value of the output signal OUT1 received from the inverter INV1 and outputs the inverted output signal OUT1 as an output signal OUT2.

The switch transistor SWT includes a PMOS transistor PM and an NMOS transistor NM. The PMOS transistor PM has a source connected to the power supply line TVDD and a drain connected to the virtual power supply line VVDD. The source and the drain of the NMOS transistor NM are in the open state. The gates of the PMOS transistor PM and the NMOS transistor NM receive the control signal OUT1 output from the control circuit CNTL.

The source and drain of the NMOS transistor NM of the switch transistor SWT may be connected to the ground line VSS or the virtual power supply line VVDD. By connecting the source and drain of the transistor to a voltage line with a fixed potential without making the source and drain unconnected, the potential of the source and drain of the transistor can be stabilized, and variation in the characteristics of the transistor can be suppressed. In addition, the charge/discharge current (leak current) in the source region and the drain region can be suppressed.

FIG. 4 shows an example in which the standard cell SC includes an inverter disposed between the virtual power supply line VVDD and the ground line VSS. For example, the transistors of the power switch circuit PSW and the standard cell SC are CFETs.

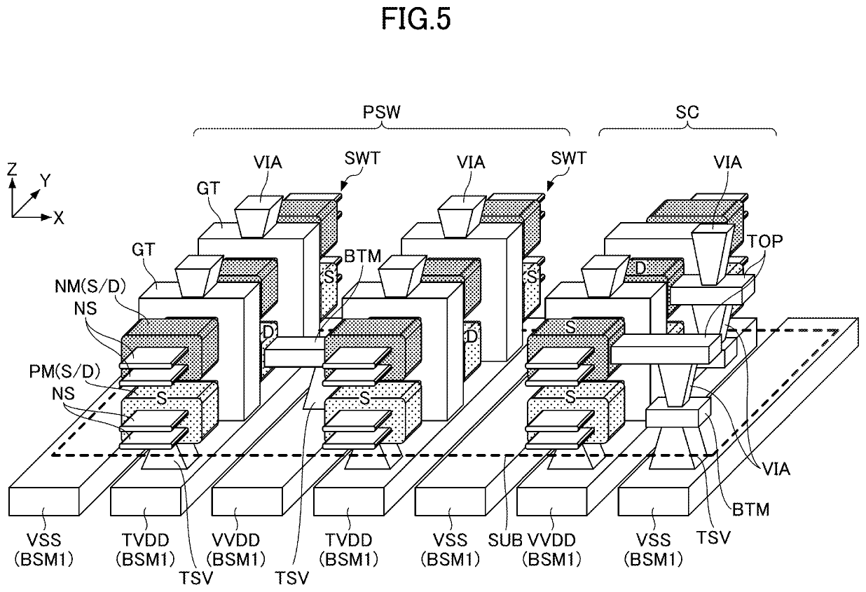

FIG. 5 shows an example of a part of the layout of the power switch circuit PSW and the standard cell SC of FIG. 3. For example, FIG. 5 shows an outline of a layout excluding the control circuit CNTL in the power switch circuit PSW and the standard cell SC of FIG. 4.

In FIG. 5, an interlayer insulating film is not illustrated, and the substrate SUB is simply illustrated by a thick broken line. In the layout shown in FIG. 5, the source S/drain D (S/D) of the PMOS transistor PM of the CFET are formed in a bottom-side semiconductor layer disposed on the substrate SUB, and the source S/drain D (S/D) of the NMOS transistor NM of the CFET are formed in a top-side semiconductor layer disposed on the bottom-side semiconductor layer. In the CFET, two bottom-side semiconductor layers are mutually connected by a bottom-side nanosheet NS, and two top-side semiconductor layers are mutually connected by a top-side nanosheet NS. In the CFET, the gate of the PMOS transistor and the gate of the NMOS transistor are common. The source S/drain D (S/D) of the NMOS transistor NM have an N-type conductivity, and the source S/drain D (S/D) of the PMOS transistor PM have a P-type conductivity. In the present disclosure, the semiconductor layer is sometimes referred to as the source S/drain D (S/D), even when the semiconductor layer does not function as a transistor. Also, a part of the structure of the CFET, even when the semiconductor layer does not function as a transistor, is sometimes referred to as the NMOS transistor NM or the PMOS transistor PM, depending on the conductivity type of the semiconductor layer.

Signs S and D attached to the source S/drain D (S/D) of the NMOS transistor NM and the PMOS transistor PM indicate the source and drain of the transistor, respectively. The source S/drain D (S/D) of the NMOS transistor NM without the signs S and D indicates, for example, that the source S/drain D (S/D) of the NMOS transistor NM is in an open state and the NMOS transistor NM does not function as a transistor.

In FIG. 5, in the power switch circuit PSW, a PMOS transistor group and an NMOS transistor group are arranged in the order of source, gate, drain, gate, and source in a Y-direction. As shown in FIG. 4, the sources and the drains of the NMOS transistors of the switch transistor SWT are set in the open state.

The PMOS transistor group and the NMOS transistor group of the power switch circuit PSW are arranged at positions overlapping with the power supply line TVDD of the BSM1 layer in a plan view. The PMOS transistor group and the NMOS transistor group of the power switch circuit PSW are arranged at offset positions in an X-direction with respect to the virtual power supply line VVDD and the ground line VSS of the BSM1 layer in a plan view.

In the power switch circuit PSW, the source of the PMOS transistor of the switch transistor SWT is directly connected to the TSV formed below the source. The TSV is connected to a power supply line TVDD (BSM1) formed on the back surface of the substrate SUB. That is, the power supply potential TVDD is supplied to the source of the PMOS transistor of the switch transistor SWT by direct contact with the TSV from the back surface of the substrate SUB. The TSV connecting the source of the PMOS transistor of the switch transistor SWT to the power supply line TVDD (BSM1) is an example of a first via.

The drain of the PMOS transistor of the switch transistor SWT is connected to the power supply line VVDD (BSM1) formed on the back surface of the substrate SUB via bottom wirings BTM extending in the X-direction and TSV. The bottom wiring BTM and the transistor on the bottom side of the CFET have portions at the same positions in a Z-direction.

In the standard cell SC, the source of the NMOS transistor is connected to the ground line VSS (BSM1) formed on the back surface of the substrate SUB via a top wiring TOP, the via VIA, bottom wirings BTM extending in the X-direction and TSV. In the standard cell SC, the drain of the NMOS transistor is connected to an upper layer wiring (not illustrated) via a top wiring TOP extending in the X-direction and a via VIA. In the standard cell SC, the drain of the NMOS transistor is connected to the bottom wiring BTM via the via VIA. The top wiring TOP and the transistor on the top side of the CFET have the same position in the Z-direction.

In the standard cell SC, the source of the PMOS transistor is directly connected to the TSV formed below the source. The TSV is connected to the power supply line VVDD (BSM1) formed on the back surface of the substrate SUB. In the standard cell SC, the drain of the PMOS transistor is connected to the top wiring TOP via the bottom wiring BTM extending in the X-direction and via VIA. In the PMOS transistor and the NMOS transistor of the standard cell SC, the gate and the semiconductor layer on the rear side in the Y-direction in FIG. 5 are set to an open state, for example, and are not used.

In the switch transistor SWT, a gate GT of each transistor is connected to an upper layer wiring (not illustrated) via the via VIA formed on the gate GT. The gate GT of the switch transistor SWT is an example of a first gate.

Note that FIG. 5 shows an example in which the power supply line TVDD (BSM1) is disposed below the switch transistor SWT and a virtual power supply line VVDD (BSM1) is disposed at an offset position in the X-direction from below the switch transistor SWT. However, the virtual power supply line VVDD (BSM1) may be disposed below the switch transistor SWT and the power supply line TVDD (BSM1) may be disposed at an offset position in the X-direction from below the switch transistor SWT.

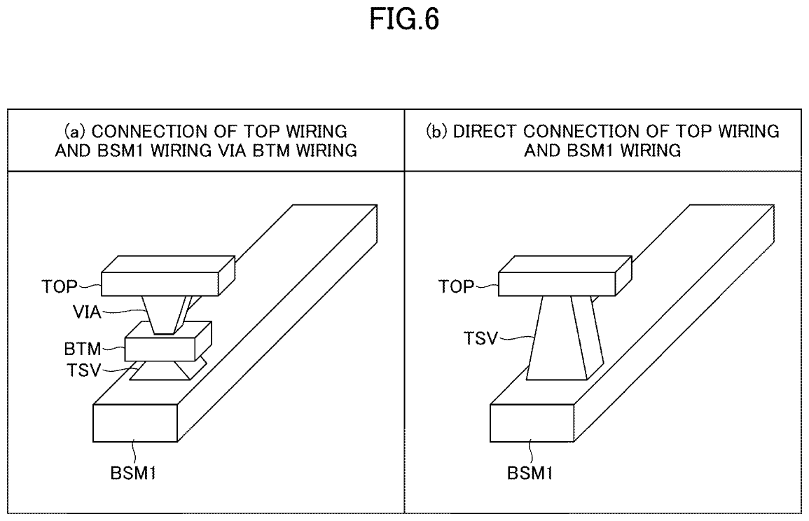

FIG. 6 shows an example of a connection method between the top wiring TOP and the wiring of the BSM1 layer formed on the back surface of the substrate. As shown in (a) of FIG. 6, the top wiring TOP and the wiring of the BSM1 layer may be connected via the bottom wiring BTM in the same manner as the wiring of the standard cell SC in FIG. 5. As shown in (b) of FIG. 6, the top wiring TOP and the wiring of the BSM1 layer may be directly connected via the TSV without passing through the bottom wiring BTM. Note that the wiring method of (b) of FIG. 6 may be applied to other embodiments.

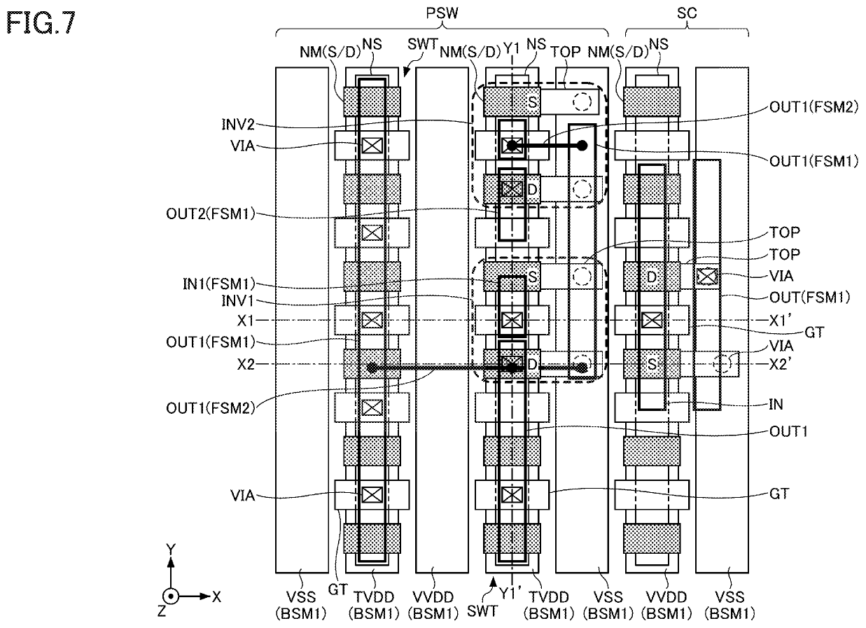

FIG. 7 shows an example of a plan view of the power switch circuit PSW and the standard cell SC of FIG. 5 as viewed from the top wiring TOP side toward the substrate SUB side. In FIG. 7, the source S/drain D (S/D) of the NMOS transistor NM without the signs S and D is in the open state or is connected to the ground line VSS, indicating that the NMOS transistor NM does not function as a transistor.

Wirings shown by a thick solid line extending in the Y-direction indicate wirings of a wiring layer FSM1 (“FSM” stands for frontside metal) disposed on the upper side of the switch transistor SWT and the standard cell SC (the side toward the position where the CFET is disposed from the substrate SUB in the Z-direction). Wirings of the wiring layer FSM1 are located on the upper side of the top wiring TOP. Wirings indicated by the thick solid line extending in the X-direction indicate wirings of the wiring layer FSM2 provided above the wiring layer FSM1. Black solid circles indicated at intersections of wirings of the wiring layers FSM1 and FSM2 indicate vias that interconnect wirings of the wiring layers FSM1 and FSM2.

In the power switch circuit PSW, the NMOS transistor NM of the switch transistor SWT and the NMOS transistors NM of the inverters INV1 and INV2 are disposed at positions overlapping with the power supply line TVDD of the BSM1 layer in a plan view, respectively. The NMOS transistors NM of the standard cell SC are disposed at positions overlapping with the virtual power supply line VVDD of the BSM1 layer in a plan view.

In the switch transistor SWT, the source of the NMOS transistor NM is an example of one of a third semiconductor layer or a fourth semiconductor layer. The drain of the NMOS transistor NM is an example of the other of the third semiconductor layer or the fourth semiconductor layer.

The source and drain of each NMOS transistor NM are disposed at positions corresponding to the formation regions of the top wirings TOP in the Z-direction. Either the source or the drain of the NMOS transistor NM is arranged on one side with respect to the gate GT in the Y-direction and the other of the source or the drain is arranged on the other side with respect to the gate GT.

The gate GT of the NMOS transistor NM of the inverter INV1 is connected to the input signal line IN1 of the wiring layer FSM1 via the via VIA. The source S of the NMOS transistor NM of the inverter INV1 is connected to the via VIA on the bottom wiring BTM side via the top wiring TOP.

The drain D of the NMOS transistor NM of the inverter INV1 is connected to the via VIA on the bottom wiring BTM side via the top wiring TOP. The drain D of the NMOS transistor NM of the inverter INV1 is connected to the output signal line OUT1 of the wiring layer FSM1 via the via VIA, the wiring of the wiring layer FSM1, the via indicated by the black solid circle, the wiring of the wiring layer FSM2, and the via indicated by the black solid circle. That is, the drain D of the NMOS transistor NM of the inverter INV1 is connected to the gate GT of the inverter INV2. Hereinafter, the wiring layer FSM1 is also referred to as the FSM1 layer, and the wiring layer FSM2 is also referred to as the FSM2 layer.

Furthermore, the wiring of the FSM2 layer connected to the drain D of the NMOS transistor NM of the inverter INV1 is connected to the output signal line OUT1 of the FSM1 layer disposed above the power supply line TVDD of the BSM1 layer, and is connected to the gate of the switch transistor SWT via the via VIA.

The gate GT of the NMOS transistor NM of the inverter INV2 is connected to the output signal line OUT1 of the FSM1 layer via the via VIA, the wiring of the FSM1 layer, the via indicated by the black solid circle, the wiring of the FSM2 layer, and the via indicated by the black solid circle. The source S of the NMOS transistor NM of the inverter INV2 is connected to the via VIA on the bottom wiring BTM side via the top wiring TOP.

The drain D of the NMOS transistor NM of the inverter INV2 is connected to the via VIA on the bottom wiring BTM side via the top wiring TOP. The drain D of the NMOS transistor NM of the inverter INV2 is connected to the output signal line OUT2 of the FSM1 layer via the via VIA.

When an inverter is formed in the standard cell SC, the gate GT of the inverter is connected to the input signal line IN of the FSM1 layer via the via VIA. The source S of the NMOS transistor NM of the inverter is connected to the via VIA on the bottom wiring BTM side via the top wiring TOP. The drain D of the NMOS transistor NM of the inverter is connected to the output signal line OUT of the FSM1 layer via the top wiring TOP and the via VIA.

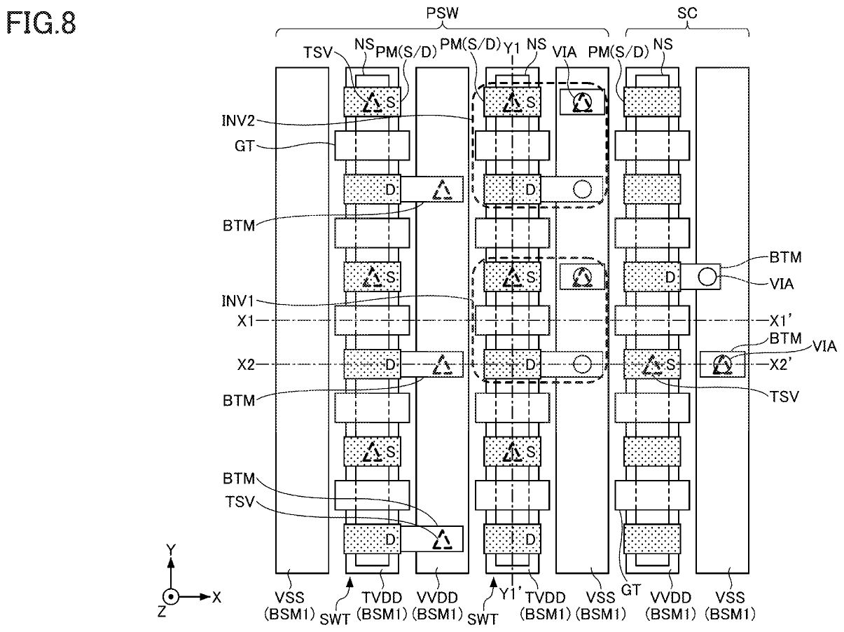

FIG. 8 shows an example of a plan view in which the power switch circuit PSW and the standard cell SC are viewed from the bottom wiring BTM side toward the substrate SUB side. In FIG. 8, the source S/drain D (S/D) of the PMOS transistor PM without the signs S and D indicates, for example, that the source S/drain D (S/D) of the PMOS transistor PM is in an open state and the PMOS transistor PM does not function as a transistor.

The source and drain of the PMOS transistor PM are arranged at positions corresponding to the formation region of the bottom wiring BTM in the Z-direction. The source and drain of the PMOS transistor PM are arranged on both sides in the Y-direction across the gate GT. The virtual power supply line VVDD of the BSM1 layer is arranged offset from the transistor row of the switch transistor SWT in a plan view.

In the switch transistor SWT, the source S of the PMOS transistor PM is directly connected to the TSV. The TSV is connected to the power supply line TVDD of the BSM1 layer. In the switch transistor SWT, the drain D of the PMOS transistor PM is connected to the virtual power supply line VVDD of the BSM1 layer via the bottom wiring BTM and the TSV. The bottom wiring BTM connected to the drain D of the PMOS transistor PM of the switch transistor SWT is an example of the first interconnect. The TSV connecting the bottom wiring BTM connected to the drain D of the PMOS transistor PM of the switch transistor SWT to the virtual power supply line VVDD of the BSM1 layer is an example of a second via.

In the switch transistor SWT, the source S of the PMOS transistor PM is an example of a first semiconductor layer, and the drain D of the PMOS transistor PM is an example of a second semiconductor layer.

When the switch transistor SWT includes a plurality of PMOS transistors PM, the drains of the plurality of PMOS transistors PM may be connected to the virtual power supply line VVDD of the BSM1 layer via a common bottom wiring BTM. Thus, the number of bottom wirings BTM connected to the drains of the PMOS transistors PM can be reduced.

In the inverter INV1, the source S of the PMOS transistor PM is directly connected to the TSV. The TSV is connected to the power supply line TVDD of the BSM1 layer. The TSV connecting the source of the PMOS transistor PM of the inverter INV1 to the power supply line TVDD is an example of a third via.

In the inverter INV1, the drain D of the PMOS transistor PM is connected to the via VIA on the top wiring TOP side via the bottom wiring BTM, and is connected to the output signal line OUT1 of FIG. 7. The drain D of the PMOS transistor PM of the inverter INV2 is connected to the via VIA on the top wiring TOP side via the bottom wiring BTM, and is connected to the output signal line OUT2 of FIG. 7.

In the inverter INV1, the source S of the PMOS transistor PM is an example of a fifth semiconductor layer, and the drain D of the PMOS transistor PM is an example of a sixth semiconductor layer. In the inverter INV1, the source of the NMOS transistor NM is an example of a seventh semiconductor layer, and the drain of the NMOS transistor NM is an example of an eighth semiconductor layer.

The gate of the inverter INV1 is an example of a second gate. The PMOS transistor PM of the inverter INV1 is an example of a second transistor. The NMOS transistor NM of the inverter INV1 is an example of a third transistor.

When an inverter is formed in the standard cell SC, the source S of the PMOS transistors PM is directly connected to the TSV. The TSV is connected to the virtual power supply line VVDD of the BSM1 layer. The drain D of the PMOS transistor PM of the inverter is connected to the drain D of the NMOS transistor NM and the output signal line OUT of FIG. 7 via the bottom wiring BTM and the via VIA.

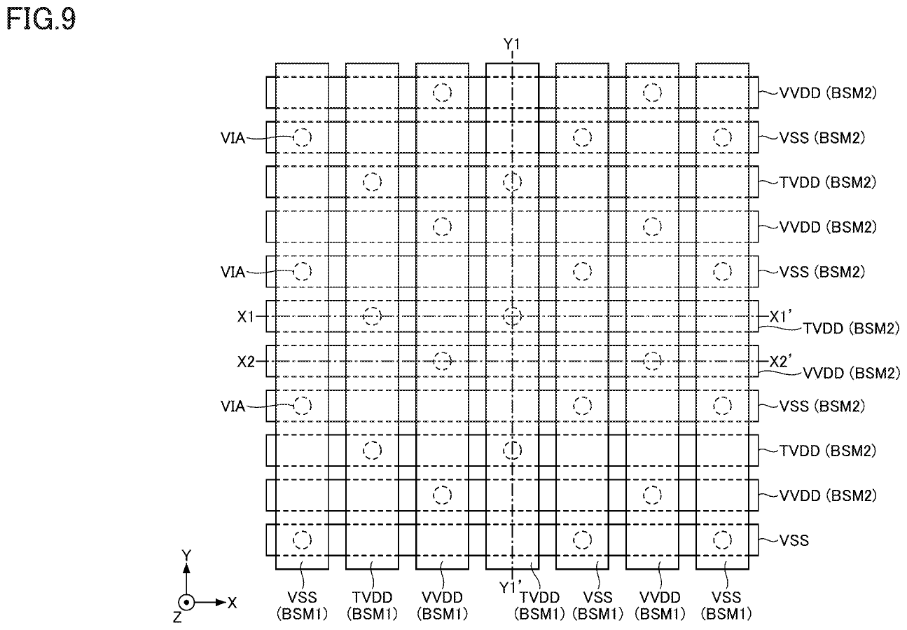

FIG. 9 shows an example of a plan view of the BSM1 layer and the BSM2 layer in a region where the power switch circuit PSW and the standard cell SC are formed. The wiring of the BSM1 layer extends in the Y-direction and is arranged at intervals in the X-direction. The wiring of the BSM2 layer extends in the X-direction and is arranged at intervals in the Y-direction.

In the BSM1 layer and the BSM2 layer, the same type of wiring (for example, the virtual power supply line VVDD) is connected to each other via the via VIA. Note that the virtual power supply line VVDD of the BSM1 layer provided in the region of the power switch circuit PSW shown in FIG. 8 is connected to the virtual power supply line VVDD of the BSM1 layer provided in the region of the standard cell SC via the virtual power supply line VVDD of the BSM2 layer.

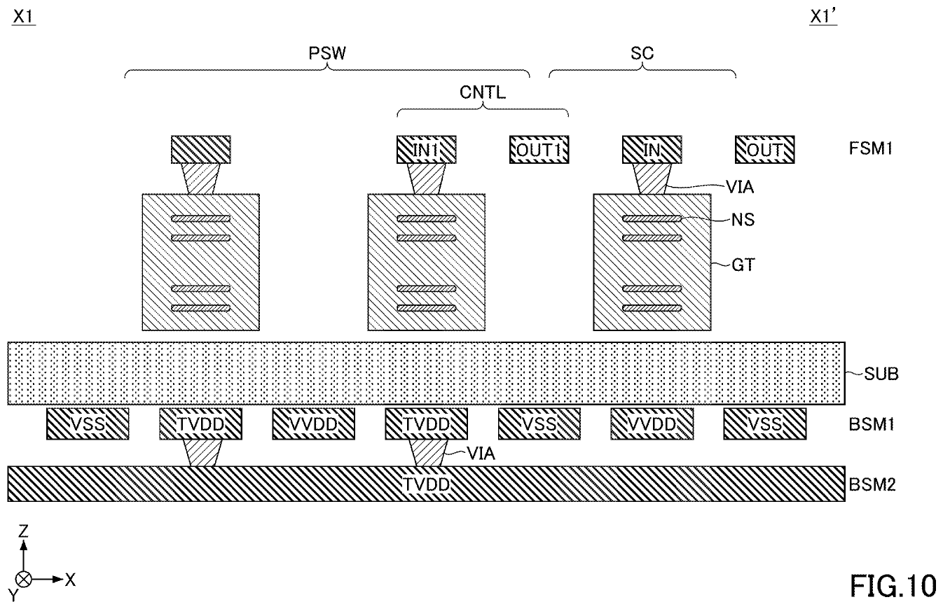

FIG. 10 shows an example of a cross section taken along a line X1-X1′ of FIGS. 7 to 9. The gate GT of each transistor is connected to the wiring of the FSM1 layer via the via VIA. The nanosheet NS is provided through the gate GT. The gate GT is arranged on the substrate SUB via an insulating film. The wiring of the BSM1 layer is disposed below the substrate SUB via an insulating film.

The wirings of the BSM1 layer and the BSM2 layer, vias VIA, and the like below the substrate SUB may be formed below the substrate SUB where the power switch circuit PSW and the like are formed by using a semiconductor manufacturing process. Alternatively, the wirings of the BSM1 layer and the BSM2 layer, vias VIA, and the like below the substrate SUB may be formed on another substrate different from the substrate SUB on which the power switch circuit PSW and the standard cell SC are formed. In this case, a wiring layer including the wirings of the BSM1 layer and the BSM2 layer, vias VIA, and the like formed on another substrate is bonded to the lower side of the substrate SUB.

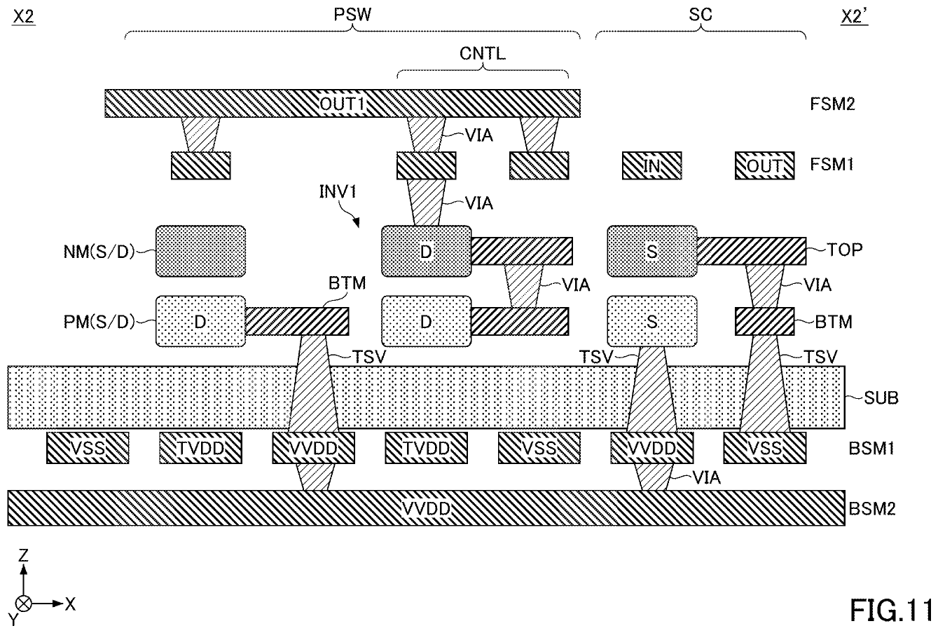

FIG. 11 shows an example of a cross section taken along a line X2-X2′ of FIGS. 7 to 9. In the power switch circuit PSW, the source S/drain D (S/D) of the NMOS transistor NM is set to the open state, and the drain D of the PMOS transistor PM is connected to the virtual power supply line VVDD of the BSM1 layer via the bottom wiring BTM and TSV.

In the inverter INV1 of the control circuit CNTL, the drain D of the NMOS transistor NM is connected to the output signal line OUT1 of the FSM2 layer via the via VIA, the wiring of the FSM1 layer, and the via VIA. In the inverter INV1 of the control circuit CNTL, the drain D of the PMOS transistor PM is connected to the drain D of the NMOS transistor NM of the inverter INV1 via the bottom wiring BTM, the via VIA, and the wiring of the top wiring TOP.

In the standard cell SC, the source S of the NMOS transistor NM is connected to the ground line VSS of the BSM1 layer via the top wiring TOP, the via VIA, the bottom wiring BTM, and TSV. The source S of the PMOS transistor PM is directly connected to the TSV. The TSV is directly connected to the virtual power supply line VVDD of the BSM1 layer.

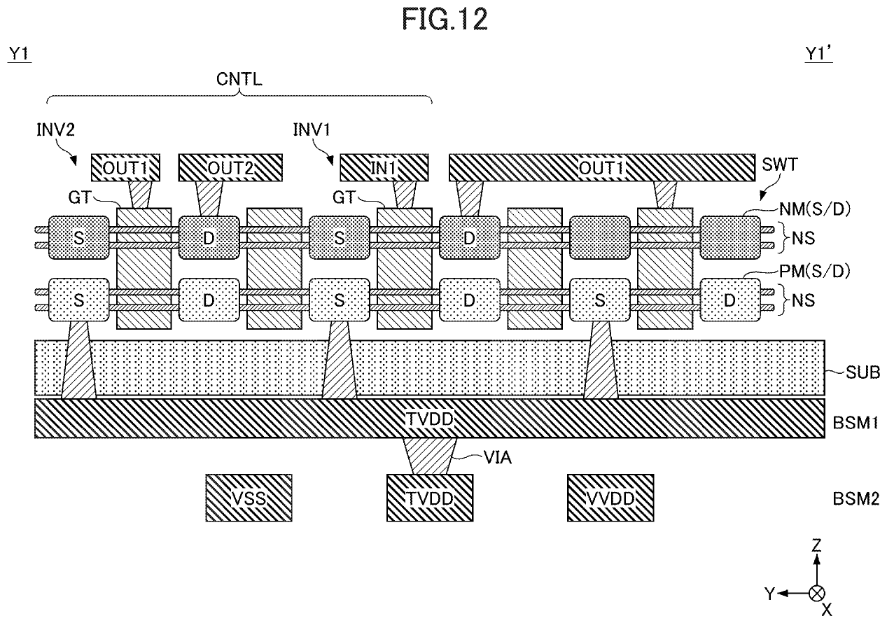

FIG. 12 shows an example of a cross section taken along a line Y1-Y1′ of FIGS. 7 to 9. In FIG. 12, the inverter INV2, the inverter INV1, and the switch transistor SWT are sequentially arranged from Y1-Y1′. The source and drain of the NMOS transistor NM of the switch transistor SWT are set to the open state and the NMOS transistor NM does not function as a transistor. The control circuit CNTL and the sources S of the PMOS transistors PM of the switch transistor SWT are directly connected to the TSV. The TSV is connected to the power supply line TVDD of the BSM1 layer. A nanosheet NS is formed between the sources S/drains D (S/D) of the NMOS transistors NM, as well as between the sources S/drains D of the PMOS transistors PM.

As described above, in the first embodiment, by connecting the source and drain of the CFET to the power supply line TVDD and the virtual power supply line VVDD formed on the back surface of the substrate SUB, the power switch circuit PSW that uses the CFET including the control circuit CNTL can be appropriately laid out. As a result, the power switch circuit PSW having a reduced circuit scale can be mounted on the semiconductor device 100.

### Second Embodiment

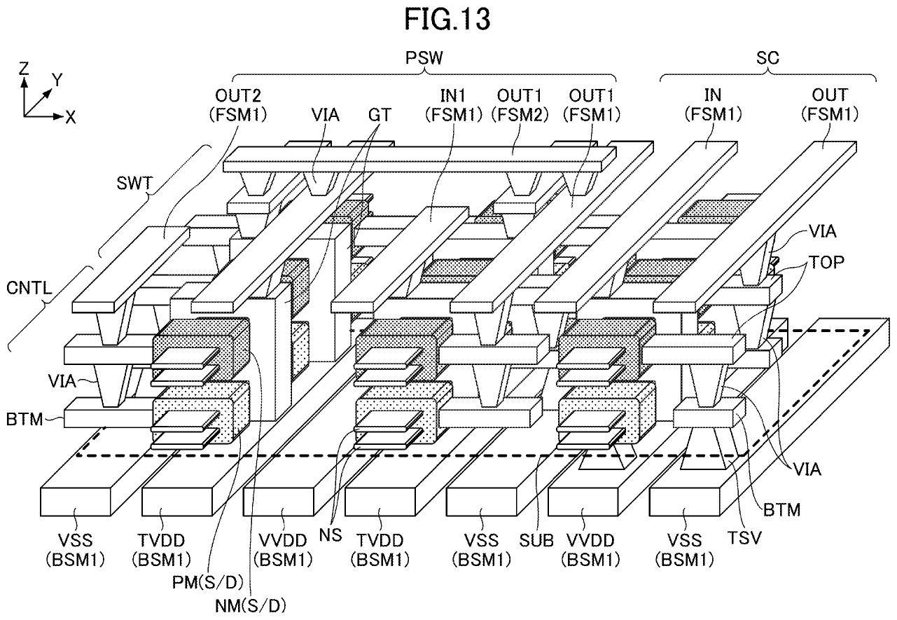

FIG. 13 shows an example of the layout of the power switch circuit and the standard cell in a second embodiment. Elements similar to those in FIG. 5 are denoted by the same signs, and detailed description thereof will be omitted. For example, the power switch circuit PSW and the standard cell SC shown in FIG. 13 are mounted on the standard cell block SCB of the semiconductor device 100 as in FIG. 1. The cross-sectional structure of the semiconductor device 100 on which the power switch circuit PSW and the standard cell SC shown in FIG. 13 are mounted is the same as in FIG. 2. The circuit arranged in the standard cell block SCB is the same as in FIG. 3. An example of the circuit of the power switch circuit PSW and the standard cell SC shown in FIG. 13 is the same as in FIG. 4, except that the sources S/drains D (S/D) of the NMOS transistors NM of the switch transistors SWT of the power switch circuit PSW are connected to the ground line VSS.

In FIG. 13, a region of the same size as the layout region as shown in FIG. 5 includes not only the switch transistor SWT and the standard cell SC but also the control circuit CNTL. For example, in the region of the power switch circuit PSW, the control circuit CNTL is formed by the source S/drain D (S/D) on the sides across the gate located on the front side in the Y-direction. In the region of the power switch circuit PSW, the switch transistor SWT is formed by the source S/drain D (S/D) on the sides across the gate located on the rear side in the Y-direction.

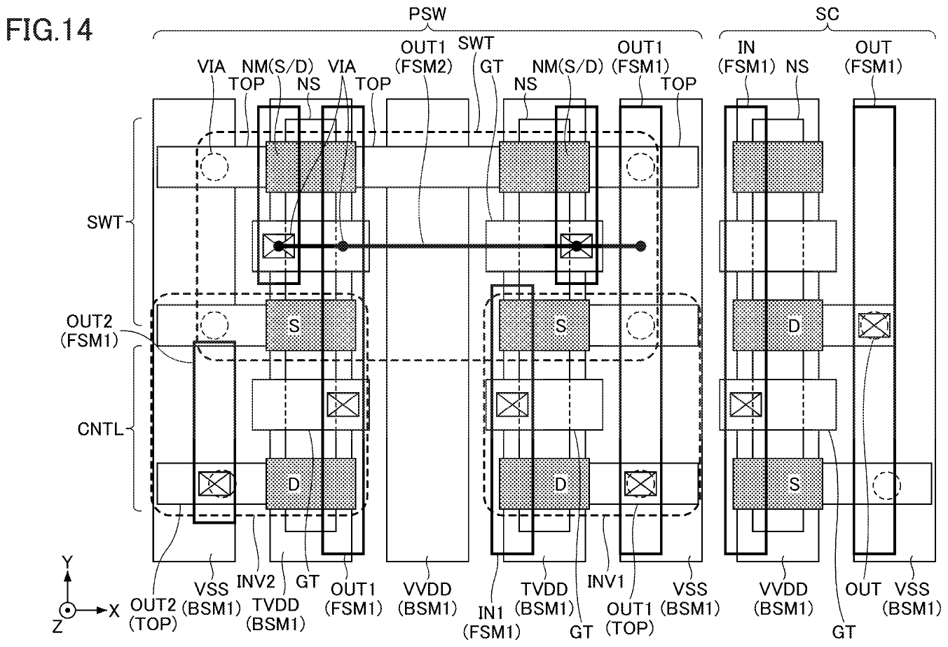

In the power switch circuit PSW, the source S/drain D (S/D) of the NMOS transistor NM is connected to the ground line VSS. By connecting the source S/drain D (S/D) of the NMOS transistor NM to a voltage line with a fixed potential without making the source S/drain D (S/D) unconnected, the potential of the source S/drain D (S/D) of the NMOS transistor NM can be stabilized, and variation in the characteristics of the power switch circuit PSW can be suppressed. In addition, the charge/discharge current (leak current) of the power switch circuit PSW can be suppressed. The wiring of the FSM1 layer and the FSM2 layer will be described with reference to FIG. 14.

FIG. 14 shows an example of a plan view of the power switch circuit PSW and the standard cell SC of FIG. 13 when viewed from the top wiring TOP side toward the substrate SUB side. Elements similar to those in FIG. 7 are denoted by the same signs, and a detailed description thereof is omitted.

The NMOS transistors NM of the switch transistors SWT of the power switch circuit PSW and the NMOS transistors NM of the inverters INV1 and INV2 of the control circuit CNTL are arranged at positions overlapping with the power supply line TVDD of the BSM1 layer in a plan view. The sources S/drains D (S/D) of the NMOS transistors NM of the switch transistors SWT are connected to the top wiring TOP extending in the X-direction in a plan view, and are further connected to the via VIA connecting the top wiring TOP to the bottom wiring BTM.

In the power switch circuit PSW, the top wiring TOP for mutually connecting the source S/drain D (S/D) of the two NMOS transistors NM arranged in the X-direction may not be formed. Alternatively, in the power switch circuit PSW, among the top wiring TOP connected to the source S/drain D (S/D) of the two NMOS transistors NM arranged in the X-direction, one of the top wiring TOP facing the ground line VSS of the BSM1 layer may not be formed.

The gate GT of the inverter INV1 is connected to the input signal line IN1 of the FSM1 layer via the via VIA. The source S of the NMOS transistor NM of the inverter INV1 is provided in common with the source S of the NMOS transistor NM of the switch transistor SWT, and is connected to the via VIA of the bottom wiring BTM side via the common top wiring TOP. By sharing the source S and the top wiring TOP, it is possible to suppress an increase in the layout size of the power switch circuit PSW.

The drain D of the NMOS transistor NM of the inverter INV1 is connected to the via VIA on the bottom wiring BTM side via the top wiring TOP, and is further connected to the output signal line OUT1 of the FSM1 layer via the upper via VIA. The output signal line OUT1 of the FSM1 layer is connected to the gate GT of the switch transistor SWT via the via indicated by the black solid circle, the wiring of the FSM2 layer, the via VIA indicated by the black solid circle, the wiring (OUT1) of the FSM1 layer, and the via VIA. Furthermore, the output signal line OUT1 of the FSM2 layer is connected to the gate of the inverter INV2 via the via VIA indicated by the black solid circle, the wiring of the FSM1 layer, and the via VIA.

The source S of the NMOS transistor NM of the inverter INV2 is provided in common with the source S of the NMOS transistor NM of the switch transistor SWT, and is connected to the via VIA on the bottom wiring BTM side via the common top wiring TOP. The drain D of the NMOS transistor NM of the inverter INV2 is connected to the via VIA on the bottom wiring BTM side via the top wiring TOP, and is further connected to the output signal line OUT2 of the FSM1 layer via the upper via VIA. The layout of the standard cell SC is similar to that of FIG. 7.

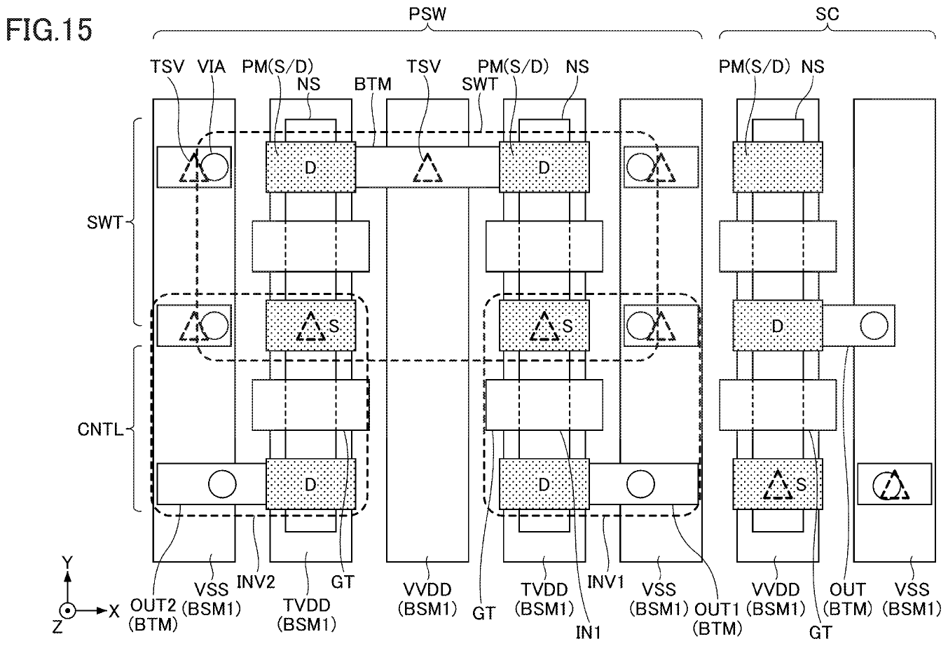

FIG. 15 shows an example of a plan view in which the power switch circuit PSW and the standard cell SC of FIG. 13 are viewed from the bottom wiring BTM side toward the substrate SUB side. Elements similar to those in FIG. 8 are denoted by the same signs, and a detailed description thereof is omitted.

The drain D of the PMOS transistor PM of the switch transistor SWT is connected to the virtual power supply line VVDD of the BSM1 layer via the bottom wiring BTM and TSV. The source S of the PMOS transistor PM of the switch transistor SWT is directly connected to the TSV. The TSV is connected to the power supply line TVDD of the BSM1 layer. The sources S of the PMOS transistors PM of the inverters INV1 and INV2 are provided in common with the source S of the PMOS transistor PM of the switch transistor SWT.

The drain D of the PMOS transistor PM of the inverter INV1 is connected to the via VIA on the top wiring TOP side via the bottom wiring BTM, and is connected to the output signal line OUT1 of FIG. 14. The drain D of the PMOS transistor PM of the inverter INV2 is connected to the via VIA on the top wiring TOP side via the bottom wiring BTM, and is connected to the output signal line OUT2 of FIG. 14. The layout of the standard cell SC is the same as that shown in FIG. 8.

In the second embodiment, as in the first embodiment, by connecting the source and drain of the CFET to the power supply line TVDD and the virtual power supply line VVDD formed on the back surface of the substrate SUB, the power switch circuit PSW using the CFET including the control circuit CNTL can be appropriately laid out. As a result, the power switch circuit PSW having a reduced circuit scale can be mounted on the semiconductor device 100.

Furthermore, in the second embodiment, by connecting the source and drain of the NMOS transistor NM of the switch transistor SWT to the ground line VSS without making the source and drain unconnected, the potential of the source and drain of the NMOS transistor NM can be stabilized, and variation in the characteristics of the NMOS transistor NM can be suppressed. In addition, the charge/discharge current (leak current) in the source region and the drain region can be suppressed.

Furthermore, by sharing the source S of the transistors of the switch transistor SWT and the control circuit CNTL, it is possible to suppress an increase in the layout size of the power switch circuit PSW. As a result, the switch transistor SWT, the control circuit CNTL, and the standard cell SC can be formed in a region of the same size as the layout region shown in FIG. 5.

Note that the first and second embodiments described above show an example of a layout in which a circuit such as an inverter of the standard cell SC is connected to the virtual power supply line VVDD and the ground line VSS, and the power switch circuit PSW generates the virtual power supply potential VVDD. However, another example may be applied to a layout in which a circuit such as an inverter of the standard cell SC is connected to a power supply line VDD and the virtual ground line VVSS, and the power switch circuit PSW generates the virtual ground potential VVSS.

In this case, the switch transistor SWT of the power switch circuit PSW may include the NMOS transistor NM connecting the ground line VSS to the virtual ground line VVSS, and the source S/drain D (S/D) of the PMOS transistor PM which is connected to the power supply line VDD or the virtual ground line VVSS and does not function as a transistor. The source S/drain D (S/D) of the PMOS transistor PM of the switch circuit PSW may be set to the open state. The switch transistor SWT may be formed only by the NMOS transistor NM, and the PMOS transistor PM may not be formed.

According to the disclosed technique, a power switch circuit formed by using a CFET whose source and drain are directly connected to a TSV can be appropriately laid out.

Although the present invention has been described based on various embodiments, the present invention is not limited to the requirements shown in the above embodiments. These points may be changed to the extent that the object of the present invention is not lost, and may be appropriately defined according to the application mode.

What is claimed is:

1. A semiconductor device comprising:
a substrate;
a first power supply line, a second power supply line, and a third power supply line formed over a first surface of the substrate;
a first semiconductor layer formed above a second surface of the substrate opposite the first surface and electrically connected to the first power supply line;
a second semiconductor layer formed above the second surface of the substrate and electrically connected to the second power supply line;
a third semiconductor layer formed at a position overlapping with the first semiconductor layer in a plan view;
a fourth semiconductor layer formed at a position overlapping with the second semiconductor layer in a plan view;
a first gate formed on the substrate between the first semiconductor layer and the second semiconductor layer and between the third semiconductor layer and the fourth semiconductor layer; and
a first transistor including the first semiconductor layer, the second semiconductor layer, and the first gate;
a first via formed in the substrate and positioned overlapping with the first semiconductor layer in a plan view and connected to the first semiconductor layer and the first power supply line;
a fifth semiconductor layer and a sixth semiconductor layer formed above the second surface of the substrate;
a seventh semiconductor layer formed on the fifth semiconductor layer;
an eighth semiconductor layer formed on the sixth semiconductor layer;
a second gate formed on the substrate between the fifth semiconductor layer and the sixth semiconductor layer and between the seventh semiconductor layer and the eighth semiconductor layer;
a second transistor including the fifth semiconductor layer, the sixth semiconductor layer, and the second gate;
a third transistor including the seventh semiconductor layer, the eighth semiconductor layer, and the second gate; and
a control circuit including the second transistor and the third transistor, wherein one of the fifth semiconductor layer or the sixth semiconductor layer is electrically connected to the first power supply line,
one of the seventh semiconductor layer or the eighth semiconductor layer is electrically connected to the third power supply line, and
the other of the fifth semiconductor layer or the sixth semiconductor layer and the other of the seventh semiconductor layer or the eighth semiconductor layer are electrically connected to the first gate.

2. The semiconductor device according to claim 1, wherein
the second power supply line is arranged offset from the first transistor in a plan view.

3. The semiconductor device according to claim 2, further comprising:
a first interconnect connected to the second semiconductor layer of the first transistor; and
a second via formed in the substrate for connecting the first interconnect and the second power supply line.

4. The semiconductor device according to claim 3, further comprising:
a plurality of the first transistors, wherein
the first interconnect is commonly connected to the second semiconductor layer of the plurality of the first transistors.

5. The semiconductor device according to claim 1, further comprising:
a third via formed in the substrate connecting the fifth semiconductor layer of the second transistor to the first power supply line.

6. The semiconductor device according to claim 1, wherein
the one of the fifth semiconductor layer or the sixth semiconductor layer is integrally formed with the first semiconductor layer, and
the third semiconductor layer is integrally formed with the one of the seventh semiconductor layer or the eighth semiconductor layer.

7. The semiconductor device according to claim 6, wherein
the third semiconductor layer and the fourth semiconductor layer are electrically connected to the third power supply line.

8. The semiconductor device according to claim 1, wherein
the first semiconductor layer, the second semiconductor layer, the fifth semiconductor layer, and the sixth semiconductor layer are of a conductivity type that differs from a conductivity type of the third semiconductor layer, the fourth semiconductor layer, the seventh semiconductor layer, and the eighth semiconductor layer.
